(19) United States
(12) Patent Application Publication
(10) Pub. No.: US 2012/0153512 A1
(43) Pub. Date: Jun. 21, 2012

(54) EPOXY RESIN COMPOSITION FOR SEMICONDUCTOR ENCAPSULATION AND SEMICONDUCTOR DEVICE OBTAINED USING THE SAME

(75) Inventors: Naoya SUGIMOTO, Osaka (JP); Tomoaki ICHIKAWA, Osaka (JP); Mitsuaki FUSUMADA, Osaka (JP); Tomohito IWASHIGE, Osaka (JP)

(73) Assignee: NITTO DENKO CORPORATION, Osaka (JP)

(21) Appl. No.: 13/333,050

(22) Filed: Dec. 21, 2011

(30) Foreign Application Priority Data
Dec. 21, 2010 (JP) 2010-285197

(51) Int. Cl. H01L 23/29

(52) U.S. Cl. 257/791; 523/435; 257/E23.117

(57) ABSTRACT

The present invention relates to an epoxy resin composition for semiconductor encapsulation, including the following components (A) to (E):(A) an epoxy resin; (B) a phenol resin other than component (C); (C) a silane-modified phenol resin represented by Formula (1) as defined in the specification; (D) a curing accelerator; and (E) an inorganic filler; wherein the component (C) is contained in an amount of 0.8 to 30.0% by weight based on a total weight of organic components in the epoxy resin composition.

### FIELD OF THE INVENTION

The invention relates to an epoxy resin composition for semiconductor encapsulation that is excellent in moldability and curability, and a semiconductor device obtained using the same.

### BACKGROUND OF THE INVENTION

Semiconductor devices have been manufactured by encapsulating a variety of semiconductor elements, such as transistors, ICs and LSIs, with plastic packages, for example, heat-curable epoxy resin compositions, from the viewpoint of protecting the semiconductor elements from external environmental factors and handling the semiconductor elements.

An important requirement for resin materials for semiconductor encapsulation, such as heat-curable epoxy resin compositions, is high reliability under high temperature and high humidity conditions. For example, high temperature or high humidity provides a good environment for ionic impurities, such as chloride ions, contained in epoxy resin compositions to act easily. For this reason, wires on semiconductor elements are prone to corrosion, and conventional epoxy resin compositions suffer from poor reliability under high temperature and high humidity conditions. The presence of ionic impurities, such as chloride ions, in epoxy resin compositions is a cause of poor reliability of the epoxy resin compositions under high temperature and high humidity conditions. The formation of such ionic impurities results from the glycidyl etherification of phenols with epihalohydrins in the course of the production of epoxy resins. High solubility of conventional cresol novolak type epoxy resins in solvents enables purification by washing with water to obtain a lower chlorine content (i.e. a higher purity). In contrast, low-viscosity crystalline epoxy resins used for a high degree of filling of inorganic fillers are difficult to purify due to their low solubility in solvents (for example, see Patent Document 1).

The use of ion scavengers including a Bi-based inorganic compound and hydrotalcite compounds has been proposed to capture ionic impurities, for example, anionic impurities, which are causes of poor reliability of epoxy resin compositions under high temperature and high humidity conditions (for example, see Patent Documents 2, 3 and 4).
Patent Document 1: JP-A-2-187420
Patent Document 2: JP-A-11-240937
Patent Document 3: JP-A-9-157497
Patent Document 4: JP-A-9-169830

### SUMMARY OF THE INVENTION

The methods of the patent documents, however, have some problems in that it is difficult to achieve a sufficient improvement in the reliability of epoxy resin compositions under high temperature and high humidity conditions, and the moldability of epoxy resin compositions is negatively affected by high viscosity.

The invention has been made in view of the above-mentioned problems, and an object of the invention is to provide an epoxy resin composition for semiconductor encapsulation that is highly reliable under high temperature and high humidity conditions and has excellent moldablity, and a semiconductor device obtained using the epoxy resin composition.

Namely, the present invention relates to the following items 1 to 4.

1. An epoxy resin composition for semiconductor encapsulation, including the following components (A) to (E):

(A) an epoxy resin;

(B) a phenol resin other than the following component (C);

(C) a silane-modified phenol resin represented by Formula (1):

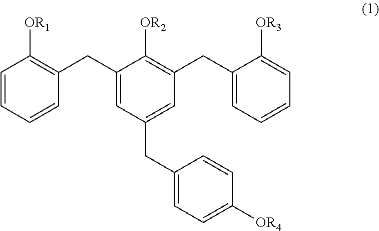

in which R₁ to R₄ may be the same or different from each other and are each independently a hydrogen atom or a monovalent functional group represented by Formula (a), provided that at least two of R₁ to R₄ are hydrogen atoms and at least one of the others is the functional group represented by Formula (a):

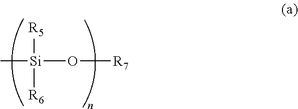

in which R₅ is an alkoxyl group, R₆ is an alkoxyl or alkyl group, R₇ is an alkyl group, and n is an integer of from 1 to 50;

(D) a curing accelerator; and

(E) an inorganic filler,

in which the component (C) is contained in an amount of 0.8 to 30.0% by weight based on a total weight of organic components in the epoxy resin composition.

2. The epoxy resin composition according to item 1, in which the component (A) is an epoxy resin having a biphenyl group.

3. The epoxy resin composition according to item 1 or 2, in which the component (D) is at least one selected from the group consisting of phosphorus-based curing accelerators represented by Formulae (2), (3) and (4):

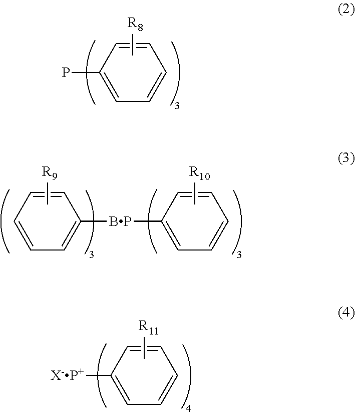

in which R₈ to R₁₁ are each independently a hydrogen atom, a fluorine atom, a chlorine atom, a bromine atom, an iodine atom, an alkyl group or an alkoxyl group, R₉ and R₁₀ may be the same or different from each other, and X is a tetraaryl group, an alkyl group, an aralkyl borate ion, a tetrafluoroborate ion, a hexafluoroantimonate ion, a hydroxide ion, a carboxylate ion, a thiocyanate ion or a dicyanamide ion.

4. A semiconductor device including a semiconductor element encapsulated with the epoxy resin composition according to any one of items 1 to 3.

The inventors have earnestly and intensively conducted research to obtain an epoxy resin composition as a material for semiconductor encapsulation that is highly reliable under high temperature and high humidity conditions without deterioration in moldability. As a result, the inventors have found that when a particular silane-modified phenol resin (component (C)) as a curing agent is used in combination with a general phenol resin to prepare an epoxy resin composition, at least one silane-modified moiety of the structure of the silane-modified phenol resin exhibits surface activity during melt flow of the epoxy resin composition to inhibit an increase in viscosity and achieve improved high-temperature, high-humidity reliability together with good moldability. On the basis of the above finding, the inventors have arrived at the invention.

Thus, the invention provides an epoxy resin composition for semiconductor encapsulation that contains a particular amount of the silane-modified phenol resin (component (C)). Due to the presence of the silane-modified phenol resin (component (C)), high reliability of the epoxy resin composition can be obtained under high temperature and high humidity conditions. In addition, low viscosity of the epoxy resin composition is ensured, leading to the manufacture of a high-reliability semiconductor device that is imparted with good moldability, for example, that can inhibit gold wires from flowing.

Further, the use of a particular phosphorus-based curing accelerator as a curing accelerator (component (D)) can ensure higher reliability under high temperature and high humidity conditions.

### BRIEF DESCRIPTION OF THE DRAWINGS

FIG. 1 is a plan view schematically illustrating a semiconductor device used to measure and evaluate the flow of a gold wire.

FIG. 2 is an explanatory view schematically illustrating a method for measuring the amount of flow of a gold wire.

### DETAILED DESCRIPTION OF THE INVENTION

Next, embodiments for carrying out the invention are described in detail.

The invention provides an epoxy resin composition for semiconductor encapsulation (hereinafter, also referred to simply as an “epoxy resin composition”) which includes an epoxy resin (component (A)), a phenol resin (component (B)), a silane-modified phenol resin (component (C)), a curing accelerator (component (D)) and an inorganic filler (component (E)). The epoxy resin composition of the invention is typically in the form of a powder, which may be compressed into a tablet.

The epoxy resin (component (A)) is not particularly limited, and examples thereof include bisphenol A type epoxy resins, phenol novolak type epoxy resins, cresol novolak type epoxy resins, biphenyl type epoxy resins, and triphenylmethane type epoxy resins. These epoxy resins may be used either alone or in combination of two or more thereof. Of these, biphenyl type epoxy resins having a biphenyl group and epoxy resins with low hygroscopicity, such as one in which lower alkyl groups are added to phenyl rings, are preferred from the viewpoint of reliability and moldability. As the epoxy resins, there may be suitably used, for example, those having an epoxy equivalent of 150 to 250 and a softening point or melting point of 50 to 130° C.

The phenol resin (component (B)) used in combination with the epoxy resin (component (A)) functions as a curing agent for the epoxy resin (component (A)). The phenol resin (component (B)) is intended to include all monomers, oligomers and polymers having two or more phenolic hydroxyl groups in one molecule, except for the silane-modified phenol resin (component (C)) as specified below. Examples of phenol resins suitable for use in the epoxy resin composition of the invention include phenol novolak resins, cresol novolak resins, biphenyl type novolak resins, triphenylmethane type phenol resins, naphthol novolak resins, phenol aralkyl resins and biphenyl aralkyl resins. These phenol resins may be used either alone or in combination of two or more thereof. Of these, phenol aralkyl resins and biphenyl aralkyl resins with low hygroscopicity are preferred from the viewpoint of reliability and moldability.

It is preferred to blend the epoxy resin (component (A)) with the phenol resin (component (B)) in such a proportion that the hydroxyl equivalent of the phenol resin (component (B)) with respect to one equivalent of the epoxy group in the epoxy resin is from 0.5 to 1.5, more preferably from 0.7 to 1.1, particularly preferably from 0.8 to 1.0.

The silane-modified phenol resin (component (C)) used in combination with component (A) and component (B) is represented by Formula (1):

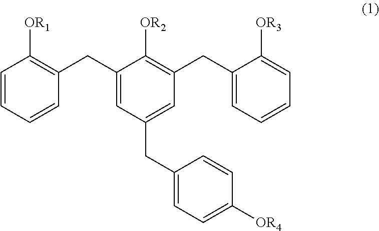

in which R₁ to R₄, which may be the same or different from each other, are each independently a hydrogen atom or a monovalent functional group represented by Formula (a), provided that at least two of R₁ to R₄ are hydrogen atoms and at least one of the others is the functional group of Formula (a):

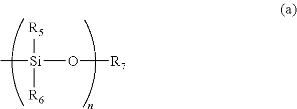

in which R₅ is an alkoxyl group, R₆ is an alkoxyl or alkyl group, R₇ is an alkyl group, and n is an integer of from 1 to 50.

In Formula (1), although each of R₁ to R₄ is a hydrogen atom or a monovalent functional group represented by Formula (a), at least two of R₁ to R₄ are hydrogen atoms and at least one of the others is the functional group of Formula (a). Particularly preferably, R₁, R₂ and R₄ are hydrogen atoms and R₃ is the functional group of Formula (a).

Further, in Formula (a), R₅ is an alkoxyl group, R₆ is an alkyl or alkoxyl group, and R₇ is an alkyl group. Particularly preferably, R₅ is a methoxy group, R₆ is a methyl or methoxy group, and R₇ is a methyl group. Additionally, the number of the repeating unit(s) n represents an integer of from 1 to 50, preferably from 1 to 30, particularly preferably from 1 to 9.

Specifically, the silane-modified phenol resin (component (C)) may be exemplified by “COMPOCERAN P501” or “COMPOCERAN P502” commercially available from Arakawa Chemical Industries, Ltd.

The content of the silane-modified phenol resin (component (C)) is limited to the range of 0.8 to 30.0% by weight, based on the total weight of the organic components in the epoxy resin composition. The content thereof is more preferably from 1.5 to 25% by weight, particularly preferably from 5.0 to 10% by weight. If the content of component (C) is too high, alcohol may be produced as a by-product during curing to affect the formation of voids, tending to disrupt a semiconductor element during encapsulation. Meanwhile, if the content of component (C) is too low, there is a tendency to make it difficult to obtain sufficient improvements in high-temperature, high-humidity reliability and moldability because voids are formed in the epoxy resin composition during flowing upon molding and are trapped by wires, resulting in an increase in resistance. Generally, the resistance of a highly viscous epoxy resin composition acting to wires increases during flowing, bringing about an increase in the amount of flow of the wires.

The curing accelerator (component (D)) used in combination with components (A) to (C) may be selected from a various kinds of curing accelerators. A phosphorus-based curing accelerator is preferred in view of high-temperature and high-humidity reliability.

Examples of phosphorus-based curing accelerators suitable for use in the epoxy resin composition of the invention include those represented by Formulae (2), (3) and (4). These phosphorus-based curing accelerators may be used either alone or in combination of two or more thereof.

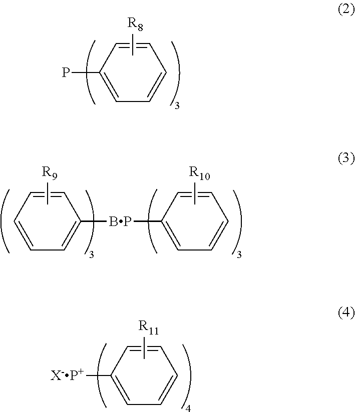

in which R₈ to R₁₁ are each independently a hydrogen atom, a fluorine atom, a chlorine atom, a bromine atom, an iodine atom, an alkyl group or an alkoxyl group, R₉ and R₁₀ may be the same or different from each other, and X is a tetraaryl group, an alkyl group, an aralkyl borate ion, a tetrafluoroborate ion, a hexafluoroantimonate ion, a hydroxide ion, a carboxylate ion, a thiocyanate ion or a dicyanamide ion.

Specific examples of the phosphorus-based curing accelerators include: phosphine compounds, e.g., organophosphines, such as triphenylphosphine, diphenyl(p-tolyl)phosphine, tris(alkylphenyl)phosphines, tris(alkoxyphenyl)phosphines, tris(alkyl.alkoxyphenyl)phosphines, tris(dialkyl)phosphines, tris(trialkylphenyl)phosphines, tris(tetraalkylphenyl)phosphines, tris(dialkoxyphenyl)phosphines, tris(trialkoxyphenyl)phosphines, tris(tetraalkoxyphenyl)phosphines, trialkylphosphines, dialkylarylphosphines and alkyldiarylphosphines; complexes of these phosphine compounds and organoborons; compounds having intramolecular polarization obtained by addition reaction of these phosphine compounds with compounds having one or more π bonds, for example, maleic anhydride, quinone compounds, such as 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone and phenyl-1,4-benzoquinone, and diazophenylmethane; and compounds having intramolecular polarization obtained by reacting these phosphine compounds with halogenated phenol compounds, such as 4-bromophenol, 3-bromophenol, 2-bromophenol, 4-chlorophenol, 3-chlorophenol, 2-chlorophenol, 4-iodophenol, 3-iodophenol, 2-iodophenol, 4-bromo-2-methylphenol, 4-bromo-3-methylphenol, 4-bromo-2,6-dimethylphenol, 4-bromo-3,5-dimethylphenol, 4-bromo-2,6-di-tert-butylphenol, 4-chloro-1-naphthol, 1-bromo-2-naphthol, 6-bromo-2-naphthol and 4-bromo-4′-hydroxybiphenyl, followed by dehydrohalogenation thereof.

Other examples of the phosphorus-based curing accelerators include tetra-substituted phosphonium salts, such as tetraphenylphosphonium tetraphenylborate, tetraphenylphosphonium tetra-p-tolylborate, tetraphenylphosphonium thiocyanate, tetraphenylphosphonium dicyanamide, tetraphenylphosphonium acetate, tetraphenylphosphonium tetrafluoroborate, tetraphenylphosphonium hexafluoroantimonate, p-tolyltriphenylphosphonium tetra-p-tolylborate, tetra-p-tolylphosphonium tetraphenylborate, tetra-p-tert-butylphenylphosphonium tetraphenylborate and tetra-p-methoxyphenylphosphonium tetraphenylborate.

The content of the curing accelerator (component (D)) is preferably set to 0.001 to 8.0% by weight, more preferably 0.01 to 3.0% by weight, based on the weight of the epoxy resin (component (A)). If the content of the component (D) is too small, a sufficient curing acceleration effect may not be expected. Meanwhile, if the content thereof is too large, a final cured product may tend to discolor.

The inorganic filler (component (E)) used in combination with components (A) to (D) may be selected from quartz glass, talc, silica powders (fused silica powders, crystalline silica powders, etc.), alumina powders, aluminum nitride powders and silicon nitride powders. These inorganic fillers may be used in any form, for example, a crushed, spherical or ground form. These inorganic fillers may be used either alone or in combination of two or more thereof. Of these, silica powders are preferred in that a cured product having a reduced linear expansion coefficient can be obtained. Fused silica powders are particularly preferred due to their high filling capacity and high flowability. The fused silica powders may be exemplified by spherical fused silica powders and crushed fused silica powders. From the viewpoint of flowability, spherical fused silica powders are preferred.

It is preferred in terms of flowability, that the inorganic filler (component (E)) have an average particle diameter of from 5 to 40 μm. The average particle diameter of the inorganic filler (component (E)) can be determined, for example, by measuring that of a random sample selected from a population using a laser diffraction/scattering particle size distribution analyzer.

The content of the inorganic filler (component (E)) is preferably set to 70 to 95% by weight, particularly preferably 85 to 92% by weight, based on the total weight of the epoxy resin composition. If the content of the inorganic filler (component (E)) is too small, the viscosity of the epoxy resin composition decreases, tending to cause poor appearance (formation of voids) upon molding. Meanwhile, if the content of the inorganic filler (component (E)) is too large, the flowability of the epoxy resin composition is deteriorated, tending to cause a flow of wires and incomplete filling.

If necessary, the epoxy resin composition for semiconductor encapsulation according to the invention may further include one or more additives, in addition to components (A) to (E). Examples of such additives include silane coupling agents, flame retardants, flame retardant aids, release agents, ion trapping agents, pigments, such as carbon black, colorants, stress reducing agents, and tackifiers.

As the silane coupling agents, there may be suitably used those having two or more alkoxy groups. Specific examples of the silane coupling agents include 3-methacryloxypropyltrimethoxysilane, β-(3,4-epoxycyclohexyl)ethyltrimethoxysilane, γ-glycidoxypropyltrimethoxysilane, γ-mercaptopropyltrimethoxysilane, γ-(2-aminoethyl)aminopropyltrimethoxysilane, γ-mercaptopropylmethyldimethoxysilane, γ-anilinopropyltrimethoxysilane and hexamethyldisilazane. These silane coupling agents may be used either alone or in combination of two or more thereof.

The flame retardants may be exemplified by novolak type brominated epoxy resins and metal hydroxides. As the flame retardant aids, there may be used, for example, diantimony trioxide and diantimony pentoxide. These flame retardant aids may be used either alone or in combination of two or more thereof.

The release agents may be exemplified by higher fatty acids, higher fatty acid esters and calcium salts of higher fatty acids. For example, carnauba waxes and polyethylene waxes may be used. These release agents may be used either alone or in combination of two or more thereof.

The ion trapping agents may be all known compounds having the ability to trap ions, for example, hydrotalcites, bismuth hydroxide and yttrium oxide. These ion trapping agents may be used either alone or in combination of two or more thereof.

Examples of the stress reducing agents include butadiene rubbers such as methyl acrylate-butadiene-styrene copolymers and methyl methacrylate-butadiene-styrene copolymers, and silicone compounds. These stress reducing agents may be used either alone or in combination of two or more thereof.

The epoxy resin composition for semiconductor encapsulation according to the invention may be prepared, for example, by the following procedure. First, components (A) to (E) and optionally one or more other additives are blended and mixed together. The mixture is melt-kneaded with heating in a kneader, such as a mixing roll. Subsequently, the kneaded mixture is cooled to room temperature to obtain a solid. The solid is pulverized by suitable means known in the art. If needed, the powder is compressed into tablets.

The thus-obtained epoxy resin composition of the invention can be used to encapsulate a semiconductor element. No particular limitation is imposed on the encapsulation method. For example, the encapsulation may be performed by any suitable known molding process, such as transfer molding, to obtain a semiconductor device. The semiconductor device may be an IC or an LSI.

### EXAMPLES

The invention will be explained with reference to the following examples and comparative examples. However, the invention is not limited to these examples.

First, the following components were prepared.

[Epoxy Resin a1]

Biphenyl type epoxy resin (epoxy equivalent: 192, melting point: 105° C.; YX-4000 manufactured by Mitsubishi Chemical Corporation).

[Epoxy resin a2]

Triphenylmethane type polyfunctional epoxy resin (epoxy equivalent: 169; melting point: 60° C.; EPPN-501 HY manufactured by Nippon Kayaku Co., Ltd.).

[Phenol resin b1]

Biphenyl aralkyl type phenol resin (hydroxyl equivalent: 203; softening point: 65° C.; MH7851SS manufactured by Meiwa Plastic Industries, Ltd.).

[Phenol resin b2]

Phenol novolak resin (hydroxyl equivalent: 104; softening point: 60° C.; VR-8210 manufactured by Mitsui Chemicals, Inc.). [Silane-modified phenol resin c1]

Trialkoxysilane condensate-modified phenol resin [hydroxyl equivalent: 270; COMPOCERAN P501 (trade name) manufactured by Arakawa Chemical Industries, Ltd.; Formula (1) in which R₁ is a hydrogen atom, R₂ is a hydrogen atom, R₃ is the functional group represented by Formula (a) (in which R₅ is a methoxy group, R₆ is a methyl group, R₇ is a methyl group, and n is an average of 5), and R₄ is a hydrogen atom]

[Silane-Modified Phenol Resin c2]

Trialkoxysilane condensate-modified phenol resin [hydroxyl equivalent: 300; COMPOCERAN P502 (trade name) manufactured by Arakawa Chemical Industries, Ltd.; Formula (1) in which R₁ is a hydrogen atom, R₂ is a hydrogen atom, R₃ is the functional group represented by Formula (a) (in which R₅ is a methoxy group, R₆ is a methoxy group, R₇ is a methyl group, and n is an average of 5), and R₄ is a hydrogen atom]

[Curing Accelerator d1]

Triphenylphosphine (manufactured by Hokko Chemical Industry Co., Ltd.)

[Curing Accelerator d2]

Tetraphenylphosphonium tetraphenylborate (manufactured by Hokko Chemical Industry Co., Ltd.)

[Curing Accelerator d3]

Triphenylphosphine-triphenylborane complex (manufactured by Hokko Chemical Industry Co., Ltd.)

[Curing Accelerator d4]

2-Phenyl-4-methyl-5-hydroxymethylimidazole (manufactured by Shikoku Chemicals Corporation)

[Inorganic Filler]

Spherical fused silica powder (average particle diameter: 13 μm)

[Pigment]

Carbon black

[Flame Retardant]

Magnesium hydroxide

[Silane Coupling Agent]

3-Methacryloxypropyltrimethoxysilane

[Release Agent]

Polyethylene oxide wax

### Examples 1 to 10 and Comparative Examples 1 to 3

As shown in Tables 1 and 2, the components were sufficiently mixed in a mixer. Each of the mixtures was melt-kneaded using a twin-screw kneader at 100° C. for 2 min. Then, the molten product was cooled to obtain a solid. The solid was pulverized to prepare an epoxy resin composition in the form a powder.

The gelation time of each of the epoxy resin compositions of Examples 1 to 10 and Comparative Examples 1 to 3 was measured by the following method. A semiconductor device sample was manufactured using each of the epoxy resin compositions. The flow of each wire was evaluated by the following method. The reliability of the semiconductor device sample under high temperature and high humidity conditions was evaluated by the following method. The results are shown in Tables 1 to 2.

<Gelation Time>

After each of the epoxy resin compositions was melted on a hot plate at 175° C., the time taken for the epoxy resin composition to gel was measured. Taking into consideration curability, a gelation time not longer than 60 sec is generally proper.

<Wire Flow>

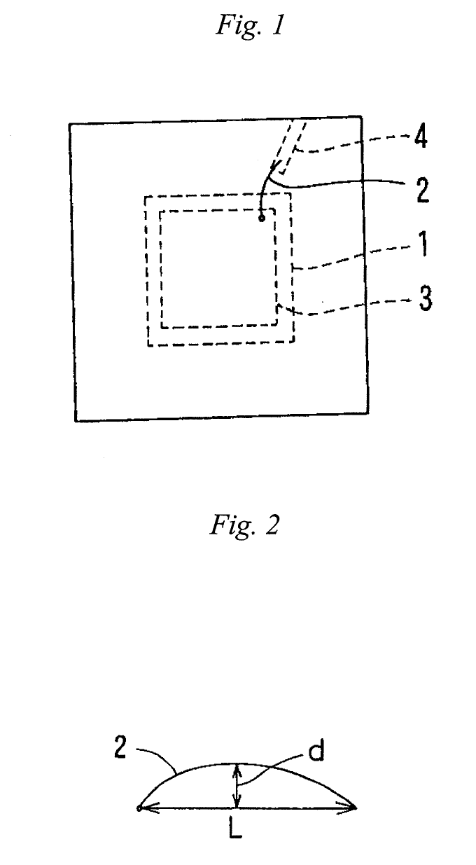

LQFP-144 (size=20 mm×20 mm×1.4 mm (thickness)) from which gold wires (diameter: 23 μm; length: 6 mm) were elongated was molded with each of the epoxy resin compositions using an automatic molding apparatus (CPS-40 L, TOWA) at 175° C. for 90 sec, followed by post-curing at 175° C. for 3 hours to manufacture a semiconductor device. FIG. 1 shows an embodiment of the semiconductor device. As shown in FIG. 1, a gold wire 2 was elongated from LQFP-144 as a package frame having a die pad 1, and the resulting structure was encapsulated with each of the epoxy resin compositions to construct a package. In FIG. 1, reference numerals 3 and 4 designate a semiconductor element and a lead pin. The amount of flow of the gold wires in the package was measured using a soft X-ray analyzer. For measurement, ten of the gold wires were selected from the package. As illustrated in FIG. 2, the amount of flow of the gold wire 2 from the front direction was measured. The distance at which the flow of the gold wire 2 reached a maximum was defined as the amount (d mm) of flow of the gold wire in the package. The flow rate of the gold wire was calculated by (d/L)×100 (where L represents the distance (mm) between both ends of the gold wire 2). The flow of the gold wire was judged to be “C” when the flow rate was 6% or higher, “B” when the flow rate was 4% or higher and lower than 6%, and “A” when the flow rate was lower than 4%.

<High-Temperature, High-Humidity Reliability>

A highly accelerated steam and temperature (HAST) test was conducted on the semiconductor device at 130° C. and 85% RH. Specifically, resistance values of the semiconductor device were measured at uniform time intervals without applying a bias voltage thereto while exposing the semiconductor device to 130° C. and 85% RH. The resistance of the semiconductor device was measured after the HAST test. The semiconductor device was judged to be poor (disconnected) when the resistance was increased by 10% or more. The time when disconnection occurred during the HAST test was defined as the reliability life under high temperature and high humidity conditions.

TABLE 1
(wt %)

| | Examples | | | | | | | | | |
|---|---|---|---|---|---|---|---|---|---|---|
| | 1 | 2 | 3 | 4 | 5 | 6 | 7 | 8 | 9 | 10 |
| Epoxy resin a1 | 4.84 | 4.79 | 4.74 | 4.5 | — | 6.25 | 4.77 | 4.79 | 4.79 | 4.79 |
| Epoxy resin a2 | — | — | — | — | 4.47 | — | — | — | — | — |
| Phenol resin b1 | 4.97 | 4.61 | 4.26 | 2.5 | 4.92 | | 4.64 | 4.61 | 4.61 | 4.61 |
| Phenol resin b2 | — | — | — | — | — | 3.15 | — | — | — | — |
| Silane-modified | 0.2 | 0.6 | 1.0 | 3.0 | 0.6 | 0.6 | — | 0.6 | 0.6 | 0.6 |
| phenol resin c1 | | | | | | | | | | |
| Silane-modified | — | — | — | — | — | — | 0.6 | — | — | — |
| phenol resin c2 | | | | | | | | | | |
| Curing accelerator | 0.3 | 0.3 | 0.3 | 0.3 | 0.3 | 0.3 | 0.3 | — | — | 0.2 |
| d1 | | | | | | | | | | |
| Curing accelerator | — | — | — | — | — | — | — | 0.5 | — | — |
| d2 | | | | | | | | | | |
| Curing accelerator | — | — | — | — | — | — | — | — | 0.5 | — |
| d3 | | | | | | | | | | |
| Curing accelerator | — | — | — | — | — | — | — | — | — | 0.1 |
| d4 | | | | | | | | | | |
| Inorganic filler | 88.69 | 88.7 | 88.7 | 88.7 | 88.71 | 88.7 | 88.69 | 88.5 | 88.5 | 88.7 |
| Pigment | 0.5 | 0.5 | 0.5 | 0.5 | 0.5 | 0.5 | 0.5 | 0.5 | 0.5 | 0.5 |
| Flame retardant | 0.1 | 0.1 | 0.1 | 0.1 | 0.1 | 0.1 | 0.1 | 0.1 | 0.1 | 0.1 |
| Silane coupling | 0.1 | 0.1 | 0.1 | 0.1 | 0.1 | 0.1 | 0.1 | 0.1 | 0.1 | 0.1 |
| agent | | | | | | | | | | |
| Release agent | 0.3 | 0.3 | 0.3 | 0.3 | 0.3 | 0.3 | 0.3 | 0.3 | 0.3 | 0.3 |
| Content (wt %) of | 1.87 | 5.61 | 9.35 | 28.04 | 5.61 | 5.61 | 5.60 | 5.50 | 5.50 | 5.61 |
| silane-modified | | | | | | | | | | |
| phenol resins^{} | | | | | | | | | | |
| Gelation time (sec) | 48 | 50 | 55 | 59 | 54 | 49 | 45 | 45 | 46 | 47 |
| Wire flow | A | A | A | B | B | A | A | A | A | A |
| Reliability life | 1050 | 2241 | 2448 | 2594 | 912 | 2100 | 2040 | 2454 | 2800 | 1544 |
| (hr) | | | | | | | | | | |

^{}The content (wt %) of silane-modified phenol resins is based on the organic components of the epoxy resin composition.

TABLE 2

| | | | (wt %) |
|---|---|---|---|
| | Comparative Examples | | |
| | 1 | 2 | 3 |
| Epoxy resin a1 | 4.86 | 4.44 | 4.86 |
| Epoxy resin a2 | — | — | — |
| Phenol resin b1 | 5.14 | 2.06 | 5.1 |
| Phenol resin b2 | — | — | — |
| Silane-modified phenol resin c1 | — | 3.5 | 0.05 |
| Silane-modified phenol resin c2 | — | — | — |
| Curing accelerator d1 | 0.3 | 0.3 | 0.2 |
| Curing accelerator d2 | — | — | — |
| Curing accelerator d3 | — | — | — |
| Curing accelerator d4 | — | — | 0.1 |
| Inorganic filler | 88.7 | 88.7 | 88.69 |
| Pigment | 0.5 | 0.5 | 0.5 |
| Flame retardant | 0.1 | 0.1 | 0.1 |
| Silane coupling agent | 0.1 | 0.1 | 0.1 |
| Release agent | 0.3 | 0.3 | 0.3 |
| Content (wt %) of silane-modified phenol | — | 32.71 | 0.47 |
| resins^{} | | | |
| Gelation time (sec) | 39 | 77 | 46 |
| Wire flow | A | C | A |
| Reliability life (hr) | 70 | 3600 | 78 |

^{}The content (wt %) of silane-modified phenol resins is based on the organic components of the epoxy resin composition.

As can be seen from the results in Tables 1 and 2, the epoxy resin compositions of Examples 1 to 10 showed good curability and also provided good results in terms of wire flow. In addition, the epoxy resin compositions of Examples 1 to 10 showed good test results for high-temperature, high-humidity reliability. These results demonstrate high reliability of the semiconductor devices.

In contrast, the epoxy resin composition of Comparative Example 1, in which the silane-modified phenol resin (component (C)) was not blended, showed very poor reliability under high temperature and high humidity conditions. The epoxy resin composition of Comparative Example 2, in which the amount of the silane-modified phenol resin (component (C)) blended was far above the upper limit of the range defined above, showed inferior curability and considerable wire flow. The epoxy resin composition of Comparative Example 3, in which the amount of the silane-modified phenol resin (component (C)) blended was far below the lower limit of the range defined above, showed very poor reliability under high temperature and high humidity conditions.

While the invention has been described in detail with reference to specific embodiments thereof, it will be apparent to one skilled in the art that various changes and modifications can be made therein without departing from the spirit and scope thereof.

Incidentally, the present application is based on Japanese Patent Application No. 2010-285197 filed on Dec. 21, 2010, and the contents are incorporated herein by reference.

All references cited herein are incorporated by reference herein in their entirety.

Also, all the references cited herein are incorporated as a whole.

The epoxy resin composition for semiconductor encapsulation according to the invention exhibits good moldability and high reliability under high temperature and high humidity conditions, thus being suitable as a material for the encapsulation of a variety of semiconductor elements.

What is claimed is:

1. An epoxy resin composition for semiconductor encapsulation, comprising the following components (A) to (E):
(A) an epoxy resin;
(B) a phenol resin other than the following component (C);
(C) a silane-modified phenol resin represented by Formula (1): 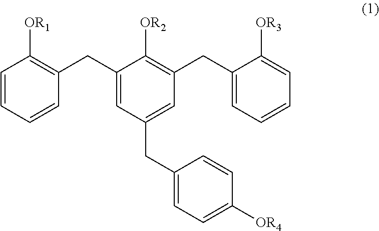
in which R₁ to R₄ may be the same or different from each other and are each independently a hydrogen atom or a monovalent functional group represented by Formula (a), provided that at least two of R₁ to R₄ are hydrogen atoms and at least one of the others is the functional group represented by Formula (a): 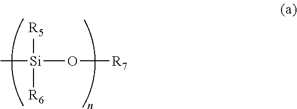
in which R₅ is an alkoxyl group, R₆ is an alkoxyl or alkyl group, R₇ is an alkyl group, and n is an integer of from 1 to 50;
(D) a curing accelerator; and
(E) an inorganic filler,
wherein the component (C) is contained in an amount of 0.8 to 30.0% by weight based on a total weight of organic components in the epoxy resin composition.

2. The epoxy resin composition according to claim 1, wherein the component (A) is an epoxy resin having a biphenyl group.

3. The epoxy resin composition according to claim 1, wherein the component (D) is at least one selected from the group consisting of phosphorus-based curing accelerators represented by Formulae (2), (3) and (4): 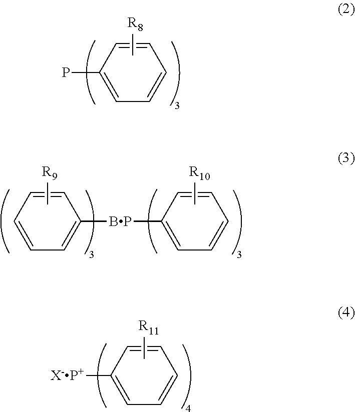
in which R₈ to R₁₁ are each independently a hydrogen atom, a fluorine atom, a chlorine atom, a bromine atom, an iodine atom, an alkyl group or an alkoxyl group, R₉ and R₁₀ may be the same or different from each other, and X is a tetraaryl group, an alkyl group, an aralkyl borate ion, a tetrafluoroborate ion, a hexafluoroantimonate ion, a hydroxide ion, a carboxylate ion, a thiocyanate ion or a dicyanamide ion.

4. The epoxy resin composition according to claim 2, wherein the component (D) is at least one selected from the group consisting of phosphorus-based curing accelerators represented by Formulae (2), (3) and (4): 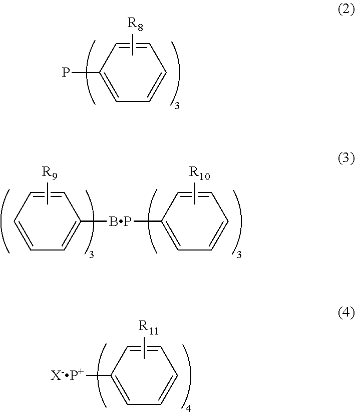
in which R₈ to R₁₁ are each independently a hydrogen atom, a fluorine atom, a chlorine atom, a bromine atom, an iodine atom, an alkyl group or an alkoxyl group, R₉ and R₁₀ may be the same or different from each other, and X is a tetraaryl group, an alkyl group, an aralkyl borate ion, a tetrafluoroborate ion, a hexafluoroantimonate ion, a hydroxide ion, a carboxylate ion, a thiocyanate ion or a dicyanamide ion.

5. A semiconductor device comprising a semiconductor element encapsulated with the epoxy resin composition according to claim 1.

6. A semiconductor device comprising a semiconductor element encapsulated with the epoxy resin composition according to claim 2.

7. A semiconductor device comprising a semiconductor element encapsulated with the epoxy resin composition according to claim 3.

8. A semiconductor device comprising a semiconductor element encapsulated with the epoxy resin composition according to claim 4.
